(19) United States
(12) Patent Application Publication
(10) Pub. No.: US 2021/0271165 A1
(43) Pub. Date: Sep. 2, 2021

(54) Photosensitive Resin Composition Cured Product Of Same

(71) Applicant: Nippon Kayaku Kabushiki Kaisha, Chiyoda-ku, Tokyo (JP)

(72) Inventors: Taihei Koumoto, Tokyo (JP); Yoshihiro Hakone, Tokyo (JP); Yoshiyuki Ono, Tokyo (JP); Takanori Koizumi, Tokyo (JP)

(21) Appl. No.: 16/967,616

(22) PCT Filed: Feb. 7, 2019
(86) PCT No.: PCT/JP2019/004383

§ 371 Date: Aug. 5, 2020

(30) Foreign Application Priority Data
Feb. 8, 2018 (JP) 2018-020659

(51) Int. Cl. G03F 7/038; G03F 7/004; C08G 59/72; C08G 59/24; C08G 59/32; C08G 59/68; C08J 5/18

(52) U.S. Cl. CPC G03F 7/0382; G03F 7/0045; C08G 59/72; C08J 5/18; C08G 59/32; C08G 59/687; C08G 59/245

(57) ABSTRACT

The present invention is a negative photosensitive resin composition which contains (A) an epoxy resin, (B) a compound that has a phenolic hydroxyl group and (C) a cationic photopolymerization initiator. This negative photosensitive resin composition is configured such that: 30% by mass or more of the epoxy resin (A) is an epoxy resin (A-1) that is represented by formula (1) (wherein each R moiety independently represents a glycidyl group or a hydrogen atom, and at least two R moieties among the plurality of R moieties are glycidyl groups; and a represents the average of the number of repeating units, which is a real number within the range of from 0 to 30); and the compound (B) that has a phenolic hydroxyl group and the cationic photopolymerization initiator (C) have specific structures.

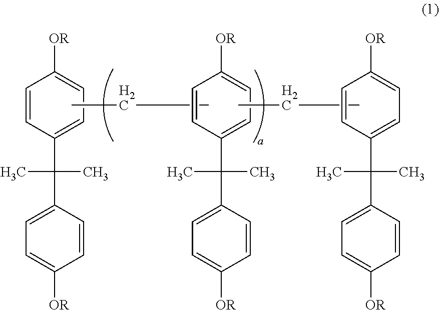

### TECHNICAL FIELD

The present invention relates to a negative photosensitive resin composition having excellent resolution, which is useful in manufacturing of microelectro mechanical system (MEMS) parts, micromachine parts, microfluid parts, μ-TAS (micro total analysis system) parts, inkjet printer parts, microreactor parts, conductive layers, LIGA parts, molds and stamps for micro injection molding and heat embossing, screens or stencils for fine printing applications. MEMS package parts, semiconductor package parts, BioMEMS and bio-photonic devices, and printed wiring boards, and a cured product of the negative photosensitive resin composition having high corrosion resistance under moist and heated conditions and also having excellent adhesion to various substrates.

### BACKGROUND ART

Recently, photolithographically processable resists have been widely used in semiconductor and MEMS-micromachine applications. In such applications, the photolithography processing is achieved by performing patterning exposure on a substrate, followed by development with a liquid developer to selectively remove exposed regions or unexposed regions. Photolithographically processable resists (photoresists) include positive type and negative type. The exposed part dissolves in a liquid developer in the case of a positive type and is insoluble therein in the case of a negative type. In the cutting-edge electropackage applications and MEMS applications, not only a capability of forming a uniform spin coating film, but also a high aspect ratio, a straight sidewall shape in a thick film, high adhesion to substrates, and the like are demanded. Here, an aspect ratio is an important property that indicates the performance of photolithography, which is calculated from the resist film thickness/pattern line width.

As such a photoresist, a negative-type chemically amplified photoresist composition containing a polyfunctional bisphenol A novolac type epoxy resin (trade name: EPON SU-8 Resin, manufactured by Resolution Performance Products LLC) and a cationic photopolymerization initiator such as CYRACURE UVI-6974 manufactured by Dow Chemical (this cationic photopolymerization initiator is composed of a propylene carbonate solution of an aromatic sulfonium hexafluoroantimonate) is known. The photoresist composition has extremely low light absorption in a wavelength range of 350 to 450 nm, and thus is known as a photoresist composition that can be processed by thick-film photolithography. When this photoresist composition is applied onto various substrates by spin coating, curtain coating, or the like, and baked to volatilize the solvent, a solid photoresist layer having a thickness of 100 μm or more can be formed. Further, when this solid photoresist layer is irradiated with near-UV light through a photomask by an exposure method such as contact exposure, proximity exposure, or projection exposure, the layer can be photolithographically processed. Subsequently, the substrate is immersed in a liquid developer to dissolve the unexposed regions, whereby a high-resolution negative image of the photomask can be formed on the substrate.

In addition, in recent years, as substrates for MEMS parts, MEMS packages, semiconductor packages, and the like, not only silicon wafers that have been conventionally generally used, but also various substrates, for example, silicon nitride, lithium tantalate, and the like are sometimes used depending on the intended use. Therefore, a cured product of a photoresist is also required to have excellent adhesion to these substrates.

Patent Literature 1 discloses a photosensitive resin composition containing a cationic photopolymerization initiator having a specified structure and a polyfunctional epoxy resin. In the examples, it is described that a cured product of the photosensitive resin composition has excellent adhesion to silicon wafers, but no mention is made of adhesion to substrates other than silicon wafers.

### CITATION LIST

### Patent Literature

PATENT LITERATURE 1: JP-A1-WO2012/008472

### SUMMARY OF INVENTION

### Technical Problem

The present invention has been accomplished against the above background, and an object thereof is to provide a negative photosensitive resin composition having excellent resolution, and a cured product thereof having excellent adhesion to silicon wafers and various substrates other than silicon wafers.

### Solution to Problem

As a result of intensive studies, the present inventors have found that the above problem can be solved by a photosensitive resin composition containing an epoxy resin having a specific structure, a compound having a phenolic hydroxyl group having a specific structure, and a cationic photopolymerization initiator having a specific structure.

That is, various aspects of the present invention for solving the above problems are as follows.

[1].

A negative photosensitive resin composition comprising (A) an epoxy resin, (B) a compound having a phenolic hydroxyl group, and (C) a cationic photopolymerization initiator, wherein

30% by mass or more of the epoxy resin (A) is

an epoxy resin (A-1) represented by the following formula (1)

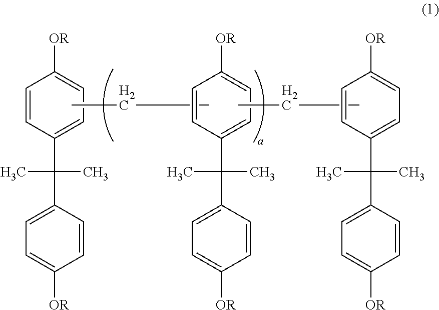

wherein Rs each independently represent a glycidyl group or a hydrogen atom, at least two of a plurality of Rs are glycidyl groups, and a represents an average value of the number of repeating units and is a real number in the range of 0 to 30, and

the compound (B) having a phenolic hydroxyl group contains one or more phenol compounds selected from a group consisting of

a compound (B-1) having a phenolic hydroxyl group represented by the following formula (2)

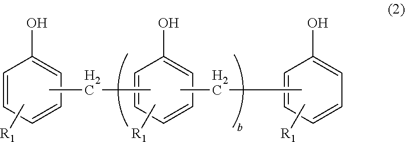

wherein b is an average value and represents a real number in the range of 1 to 10, and R₁s each independently represent a hydrogen atom or an alkyl group having 1 to 4 carbon atoms.

a compound (B-2) having a phenolic hydroxyl group represented by the following formula (3)

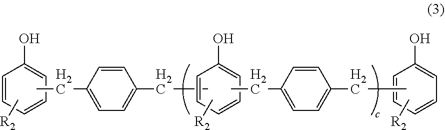

wherein c is an average value and represents a real number in the range of 1 to 10, and R₂s each independently represent a hydrogen atom or an alkyl group having 1 to 4 carbon atoms,

a compound (B-3) having a phenolic hydroxyl group represented by the following formula (4)

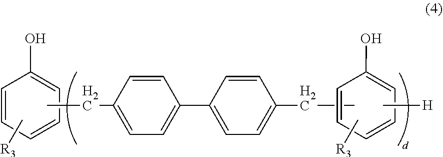

wherein d is an average value and represents a real number in the range of 1 to 10, and R₃s each independently represent a hydrogen atom or an alkyl group having 1 to 4 carbon atoms,

a compound (B-4) having a phenolic hydroxyl group represented by the following formula (5)

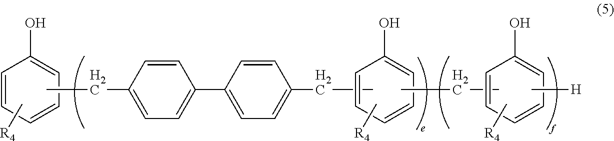

wherein e and f are average values and represent real numbers in the range of 1 to 10, and R₄s each independently represent a hydrogen atom or an alkyl group having 1 to 4 carbon atoms,

a compound (B-5) having a phenolic hydroxyl group represented by the following formula (6)

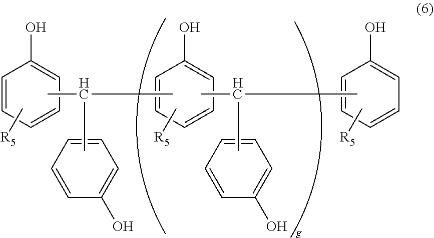

wherein g is an average value and represents a real number in the range of 1 to 10, and R₅s each independently represent a hydrogen atom or an alkyl group having 1 to 4 carbon atoms, and

a compound (B-6) having a phenolic hydroxyl group represented by the following formula (7)

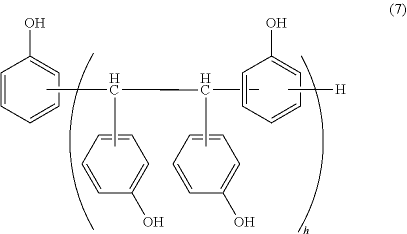

wherein h is an average value and represents a real number in the range of 1 to 10, and

the cationic photopolymerization initiator (C) contains a compound represented by the following formula (8),

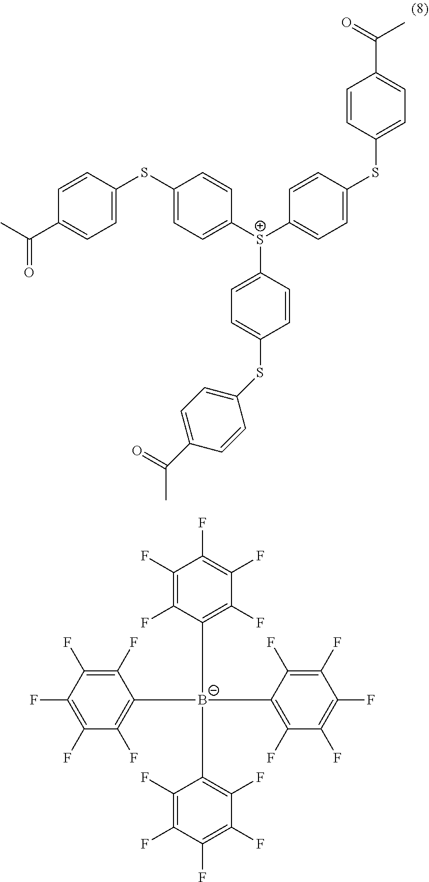 [SMILES: CC(=O)c1ccc(Sc2ccc([S+](c3ccc(Sc4ccc(C(C)=O)cc4)cc3)c3ccc(Sc4ccc(C(C)=O)cc4)cc3)cc2)cc1 ; Fc1c(F)c(F)c([B-](c2c(F)c(F)c(F)c(F)c2F)(c2c(F)c(F)c(F)c(F)c2F)c2c(F)c(F)c(F)c(F)c2F)c(F)c1F]

The negative photosensitive resin composition according to the above item [1], wherein

the epoxy resin (A) further comprises one or more epoxy resins selected from a group consisting of

an epoxy resin (A-2) represented by the following formula (9)

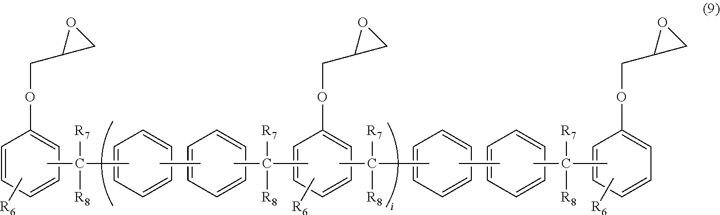

wherein R₆, R₇, and R₈ each independently represent a hydrogen atom or an alkyl group having 1 to 4 carbon atoms, and i represents an average value and is a real number in the range of 1 to 30,

an epoxy resin (A-3) represented by the following formula (10)

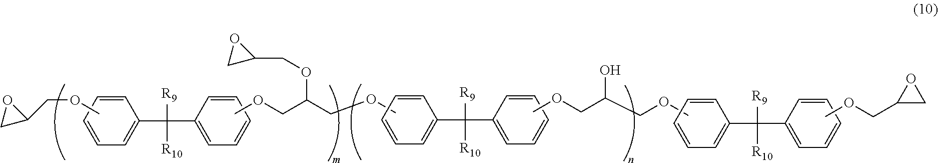

wherein m and n represent average values and are real numbers in the range of 1 to 30, and R₉ and R₁₀ each independently represent a hydrogen atom, an alkyl group having 1 to 4 carbon atoms, or a trifluoromethyl group,

an epoxy resin (A-4) represented by the following formula (11)

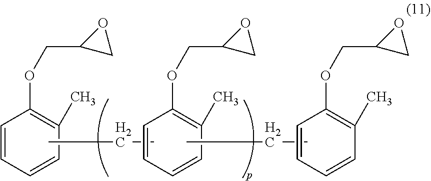

wherein p represents an average value and is a real number in the range of 1 to 30,

an epoxy resin (A-5) which is a reaction product of a phenol derivative represented by the following formula 12

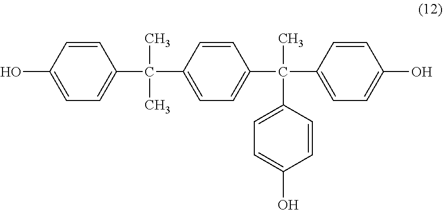 [SMILES: CC(C)(c1ccc(O)cc1)c1ccc(C(C)(c2ccc(O)cc2)c2ccc(O)cc2)cc1]

and an epihalohydrin,

an epoxy resin (A-6) obtained by reacting a polybasic acid anhydride with a reaction product of an epoxy compound having at least two epoxy groups in one molecule and a compound having at least one hydroxyl group and one carboxyl group in one molecule.

an epoxy resin (A-7) represented by the following formula (13)

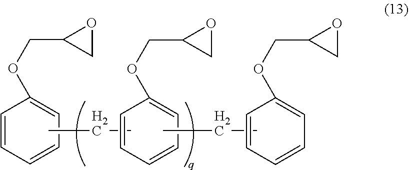

wherein q represents an average value and is a real number in the range of 1 to 10,

an epoxy resin (A-8) represented by the following formula (14)

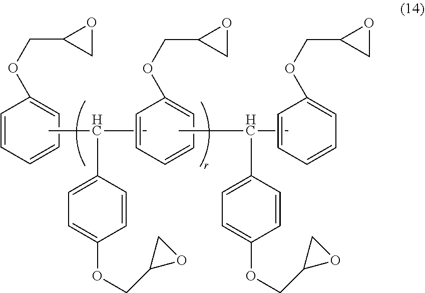

wherein r represents an average value and is a real number in the range of 0.1 to 5, and

an epoxy resin (A-9) represented by the following formula (15)

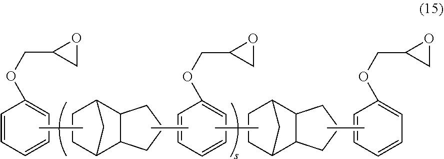

wherein s represents an average value and is a real number in the range of 0.1 to 6.

[3].

A dry film resist comprising the negative photosensitive resin composition according to the above item [1] or [2].

[4].

A cured product of the negative photosensitive resin composition according to the above item [1] or [2].

[5].

A cured product of the dry film resist according to the above item [3].

[6].

A wafer level package comprising the cured product according to the above item [4] or [5].

[7].

An adhesive layer between a substrate and an adherend, wherein the adhesive layer comprises the cured product according to the above item [4] or [5].

### Advantageous Effects of Invention

The negative photosensitive resin composition of the present invention has excellent resolution and excellent adhesion to not only silicon wafers but also various substrates other than silicon wafers, and further contains no antimony compound having high toxicity, and thus can reduce load to a human body and an environment and suppress metal corrosion, so that it is suitably used for MEMS parts, micromachine parts, semiconductor package parts, and the like.

### DESCRIPTION OF EMBODIMENTS

Hereinafter, the present invention will be described.

The negative photosensitive resin composition of the present invention contains (A) an epoxy resin (hereinafter, also simply referred to as “component (A)”), (B) a compound having a phenolic hydroxyl group (hereinafter, also simply referred to as “component (B)”), and (C) a cationic photopolymerization initiator (hereinafter, also simply referred to as “component (C)”).

In the epoxy resin (A) contained in the negative photosensitive resin composition of the present invention, it is required that 30% by mass or more of the epoxy resin (A) is an epoxy resin (A-1) represented by the formula (1).

In the formula (1), Rs each independently represent a glycidyl group or a hydrogen atom, and at least two of a plurality of Rs are glycidyl groups. The symbol “a” represents an average value of the number of repeating units and is a real number in the range of 0 to 30. Specific examples of the epoxy resin (A-1) represented by the formula (1) include KM-N-LCL (trade name, bisphenol A novolac type epoxy resin, manufactured by Nippon Kayaku Co., Ltd., epoxy equivalent of 195 to 210 g-eq., softening point of 78 to 86° C.), EPIKOTE 157 (trade name, bisphenol A novolac type epoxy resin, manufactured by Mitsubishi Chemical Corporation, epoxy equivalent of 180 to 250 g/eq., softening point of 80 to 90° C.), EPON SU-8 (trade name, bisphenol A novolac type epoxy resin, manufactured by Resolution Performance Products LLC, epoxy equivalent of 195 to 230 g/eq., softening point of 80 to 90° C.), and the like.

In the present invention, for example, the epoxy resin represented by the formula (1) means an epoxy resin whose main component is the epoxy resin represented by the formula (1) (although not particularly limited, the ratio of the epoxy resin represented by the formula (1) is preferably 80% by mass or more), and also includes by-products at the manufacturing of the epoxy resin, polymers of the epoxy resin, and the like. The same applies to epoxy resins represented by formulae other than the formula (1).

The epoxy equivalent of component (A) contained in the negative photosensitive resin composition of the present invention is preferably 150 to 500, and more preferably 150 to 450. The “epoxy equivalent of component (A)” as used herein means an epoxy equivalent of a mixture of all epoxy resins contained in the negative photosensitive resin composition of the present invention.

The molecular weight of component (A) contained in the negative photosensitive resin composition of the present invention is preferably 500 to 15,000, and more preferably 500 to 9,000. The “molecular weight of component (A)” as used herein means an average molecular weight of the mixture of all epoxy resins contained in the negative photosensitive resin composition of the present invention.

The softening point of component (A) contained in the negative photosensitive resin composition of the present invention is preferably 40 to 120° C., and more preferably 55° C. to 110° C. The “softening point of component (A)” as used herein means a softening point of the mixture of all the epoxy resins contained in the negative photosensitive resin composition of the present invention.

Incidentally, the epoxy equivalent in the present invention is a value measured by a method in accordance with JIS K7236, the molecular weight is a weight-average molecular weight value calculated in terms of polystyrene based on the measurement result of gel permeation chromatography, and the softening point is a value measured by a method in accordance with JIS K7234.

In the epoxy resin (A) contained in the negative photosensitive resin composition of the present invention, 30% by mass or more thereof only needs to be the epoxy resin (A-1) represented by the formula (1). In other words, it may contain less than 70% by mass of an epoxy resin(s) other than the epoxy resin (A-1) represented by the formula (1).

The epoxy resin other than the epoxy resin (A-1) which may be contained in the epoxy resin (A) is not particularly limited, and examples thereof include long-chain bisphenol type epoxy resins such as a long-chain bisphenol A type epoxy resin and a long-chain bisphenol F type epoxy resin, novolac type epoxy resins obtained by allowing a novolac, which is obtained by a reaction between a phenol compound (e.g., phenol, an alkyl-substituted phenol, naphthol, an alkyl-substituted naphthol, dihydroxybenzene, dihydroxynaphthalene, or the like) and formaldehyde in the presence of an acidic catalyst, to react with a halohydrin such as epichlorohydrin or methylepichlorohydrin, and the like. One or more epoxy resins selected from a group consisting of the epoxy resins (A-2), (A-3), (A-4), (A-5), (A-6), (A-7), (A-8), and (A-9) are preferable because chemical resistance, plasma resistance, and transparency of a cured product thereof are high, and further the cured product has low moisture absorption, or the like. One or more epoxy resins selected from a group consisting of (A-2) and (A-3) are more preferable, and it is further preferable to mix (A-2) and (A-3) into (A-1) and use the mixture.

In the formula (9), R₆, R₇, and R₈ each independently represent a hydrogen atom or an alkyl group having 1 to 4 carbon atoms. The symbol “i” represents an average value and is a real number in the range of 1 to 30.

Specific examples of the epoxy resin (A-2) represented by the formula (9) include NC-3000 series such as NC-3000H (trade name, biphenyl-phenol novolac type epoxy resin, manufactured by Nippon Kayaku Co., Ltd., epoxy equivalent of 270 to 300 g-eq., softening point of 55 to 75° C.).

In the formula (10), m and n represent average values and are real numbers in the range of 1 to 30, and R₉ and R₁₀ each independently represent a hydrogen atom, an alkyl group having 1 to 4 carbon atoms, or a trifluoromethyl group.

Specific examples of the epoxy resin (A-3) represented by the formula (10) include NER-7604 and NER-7403 (both are trade names, bisphenol F type epoxy resin with partially epoxidized alcoholic hydroxyl groups, manufactured by Nippon Kayaku Co., Ltd., epoxy equivalent of 200 to 500 g/eq., softening point of 55 to 75° C.), NER-1302 and NER-7516 (both are trade names, bisphenol A type epoxy resin with partially epoxidized alcoholic hydroxyl groups, manufactured by Nippon Kayaku Co., Ltd., epoxy equivalent of 200 to 500 g/eq., softening point of 55 to 75° C.), and the like.

In the formula (11), p represents an average value and is a real number in the range of 1 to 30.

Specific examples of the epoxy resin (A-4) represented by the formula (11) include EOCN-1020 (trade name, manufactured by Nippon Kayaku Co., Ltd., epoxy equivalent of 190 to 210 g/eq., softening point of 55 to 85° C.).

The epoxy resin (A-5) is a reaction product of the phenol derivative represented by the formula (12) and an epihalohydrin.

Examples of a general synthetic method of the epoxy resin (A-5) include a method in which an alkali such as sodium hydroxide is added to a mixed solution obtained by dissolving a phenol derivative represented by the formula (12) and an epihalohydrin (epichlorohydrin, epibromohydrin, or the like) in a solvent capable of dissolving them, the mixture is heated to a reaction temperature to perform an addition reaction and a ring closure reaction, then the reaction mixture is washed with water and separated and the aqueous layer is removed repeatedly, and finally the solvent is distilled off from the oil layer.

It is known that an epoxy resin (A-5) containing a different main component therein can be obtained, depending on the use ratio of the phenol derivative represented by the formula (12) and the epihalohydrin used in the synthetic reaction. For example, when an excess amount of epihalohydrin is used with respect to phenolic hydroxyl groups of the phenol derivative, an epoxy resin (A-5) whose main component is a trifunctional epoxy resin in which all three phenolic hydroxyl groups in the formula (12) are epoxidized is obtained. On the other hand, with a decrease in the amount of epihalohydrin used with respect to phenolic hydroxyl groups, phenolic hydroxyl groups of a plurality of the phenol derivative are linked to each other via the epihalohydrin, and the content of a polyfunctional epoxy resin having a large weight-average molecular weight, in which the remaining phenolic hydroxyl groups are epoxidized, increases.

Examples of a method for obtaining the epoxy resin (A-5) whose main component is such a polymeric epoxy resin include, in addition to the method of controlling the use ratio of the phenol derivative and the epihalohydrin, a method in which the epoxy resin (A-5) is further allowed to react with a phenol derivative. The epoxy resin (A-5) obtained by the method is also included in the category of the epoxy resin (A-5) contained in the photosensitive resin of the present invention.

The reaction between the phenol derivative represented by the formula (12) and the epihalohydrin is performed using the epihalohydrin in a proportion of usually 0.3 to 30 mol, preferably 1 to 20 mol, and more preferably 3 to 15 mol per mole of the phenol derivative (equivalent to 3 mol of hydroxyl groups).

As the epoxy resin (A-5) contained in the resin composition of the present invention, as long as it is an epoxy resin obtained by the reaction between the phenol derivative represented by the formula (12) and the epihalohydrin, the epoxy resin (A-5) whose main component is any of an epoxy resin that is a monomer of the phenol derivative or an epoxy resin that is an oligomer or polymer of the phenol derivative can be used. Because the epoxy resin (A-5) has excellent solvent solubility and a low softening point and is easy to handle, the epoxy resin (A-5) whose main component is an epoxy resin that is a monomer of a phenol derivative, an epoxy resin that is a dimer of a phenol derivative (i.e., an epoxy resin having a structure in which two phenol derivatives represented by the formula (12) are linked via an epihalohydrin), or an epoxy resin that is a trimer of a phenol derivative (i.e., an epoxy resin having a structure in which three phenol derivatives represented by the formula (12) are linked via an epihalohydrin) is preferable. The epoxy resin (A-5) whose main component is an epoxy resin that is a monomer of a phenol derivative or an epoxy resin that is a dimer of a phenol derivative is more preferable.

The specific structure of the epoxy resin (A-5) that is a monomer of the phenol derivative represented by the formula (12) is shown below in the formula (12-1).

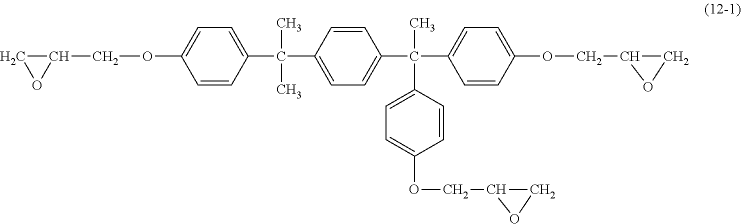 [SMILES: CC(C)(c1ccc(OCC2CO2)cc1)c1ccc(C(C)(c2ccc(OCC3CO3)cc2)c2ccc(OCC3CO3)cc2)cc1]

The specific structure of the epoxy resin (A-5) that is a dimer of the phenol derivative represented by the formula (12) is shown below in the following formula (12-2).

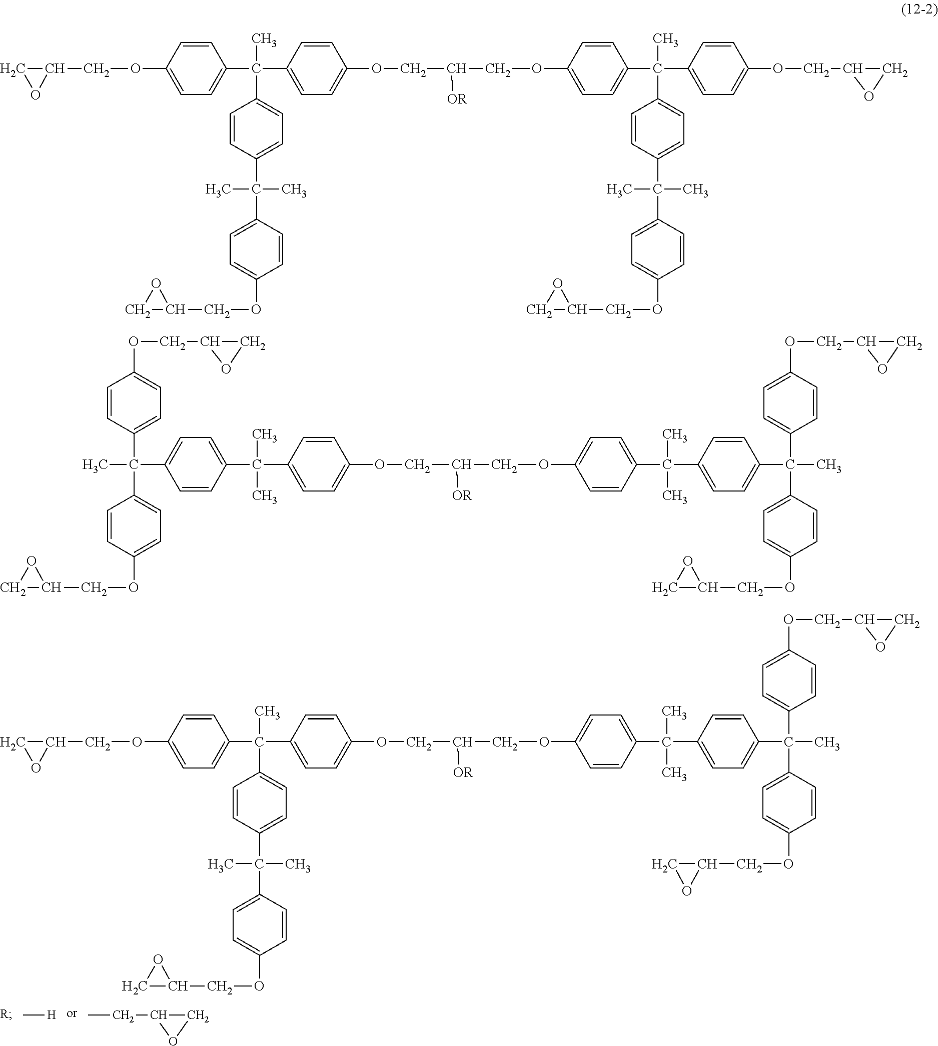

The specific structure of the epoxy resin (A-5) that is a trimer of the phenol derivative represented by the formula (12) is shown below in the following formula (12-3).

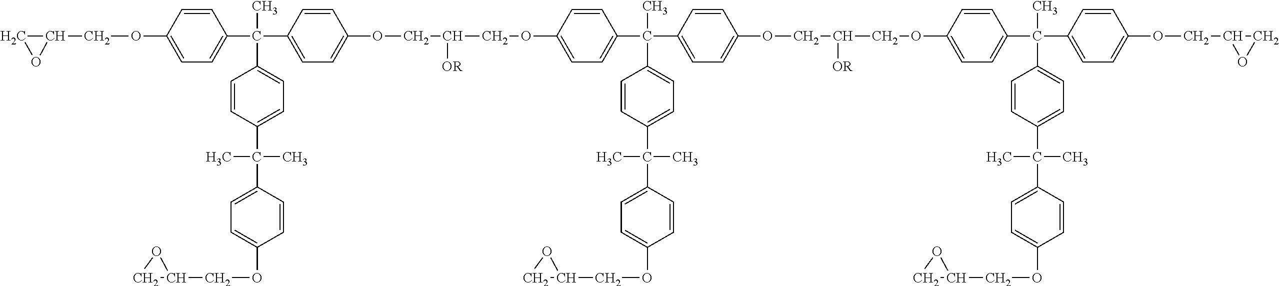

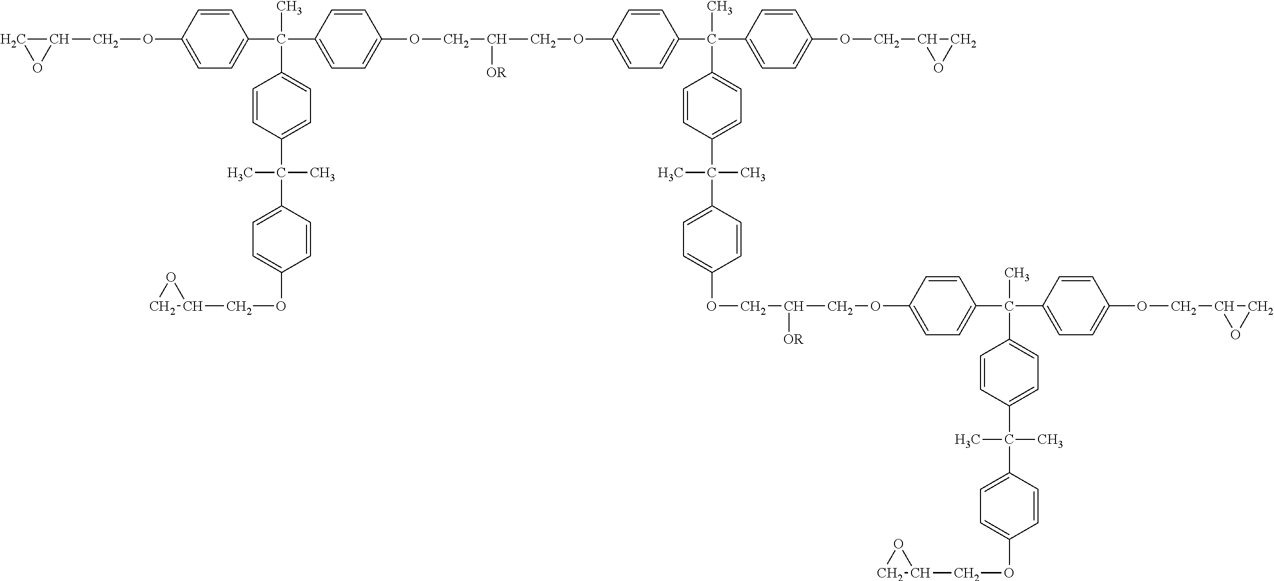

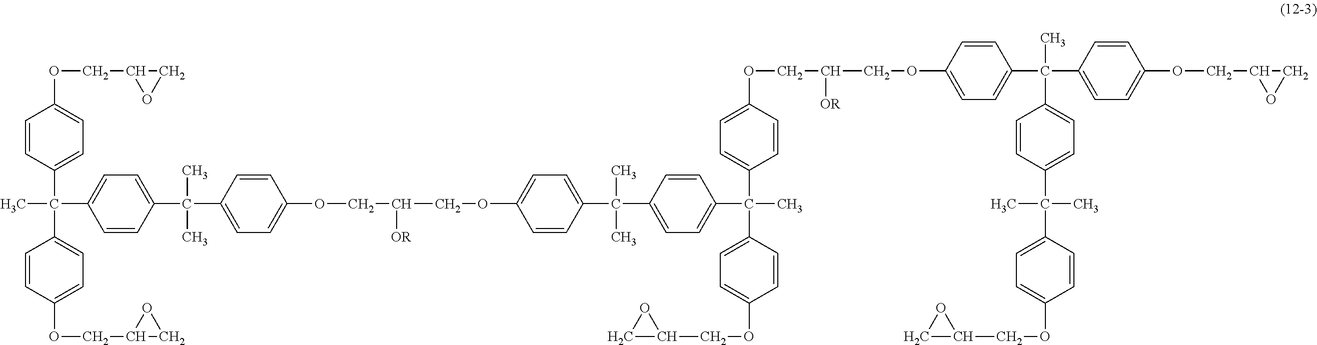

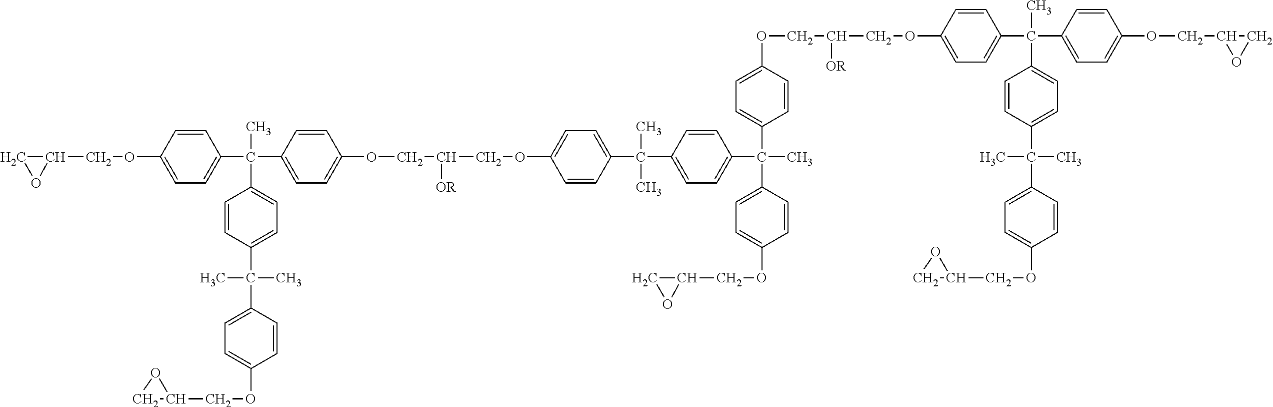

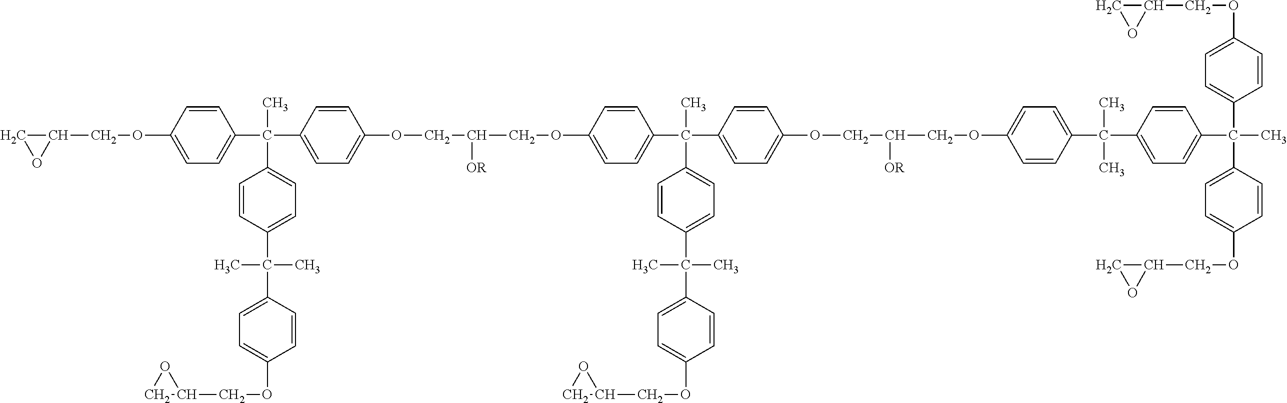

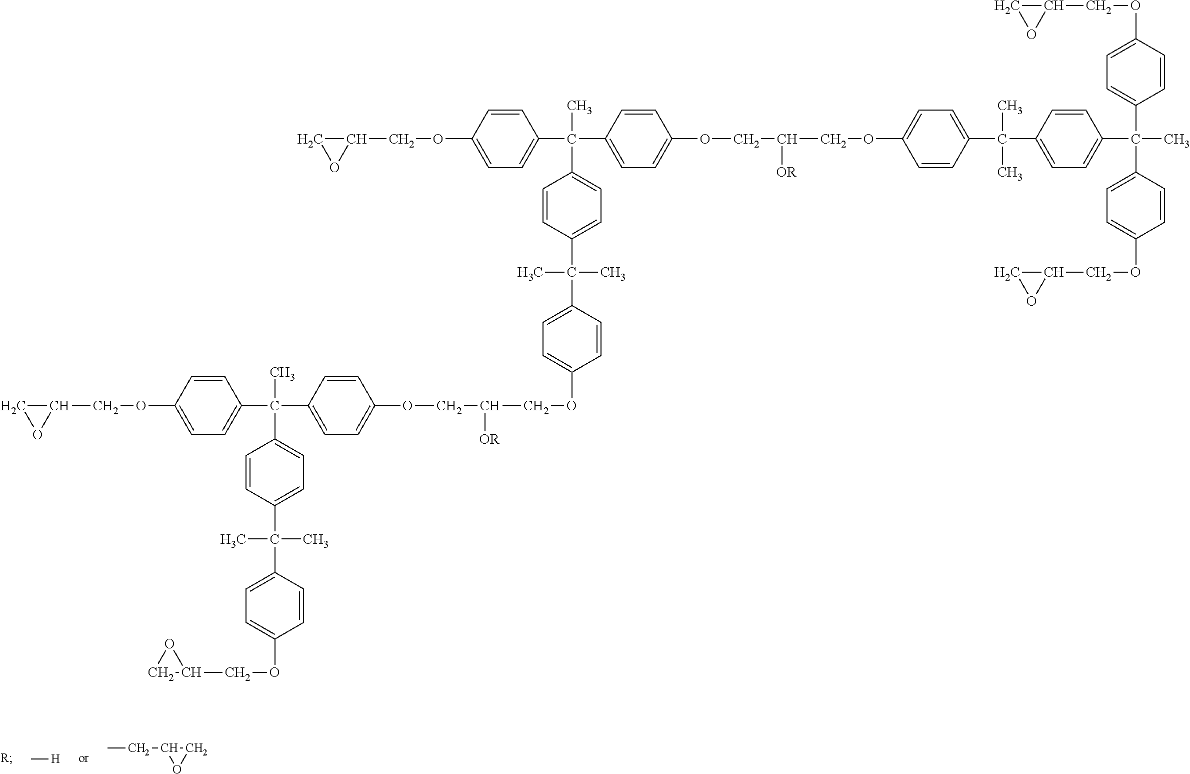

Specific examples of the epoxy resin (A-5), which is a reaction product of the phenol derivative represented by the formula (12) and the epihalohydrin, include NC-6300 (trade name, manufactured by Nippon Kayaku Co., Ltd., epoxy equivalent of 230 to 235 g/eq., softening point of 70 to 72° C.).

The epoxy resin (A-6) is a reaction product of an epoxy compound having at least two epoxy groups in one molecule and a compound having at least one hydroxyl group and one carboxyl group in one molecule, and a polybasic acid anhydride.

Examples of the epoxy resin (A-6) include polycarboxylic acid epoxy compounds whose production method is described in JP-B-2698499. The epoxy equivalent and the softening point thereof can be variously adjusted depending on the kind of the epoxy resin used as a raw material for the epoxy resin (A-6) and the introduction rate of the substituent to be introduced.

In the formula (13), q represents an average value and is a real number in the range of 1 to 10.

Specific examples of the epoxy resin (A-7) represented by the formula (13) include EPPN-201-L (trade name, manufactured by Nippon Kayaku Co., Ltd., epoxy equivalent of 180 to 200 g/eq., softening point 65 to 78° C.).

In the formula (14), r represents an average value and is a real number in the range of 0.1 to 5.

Specific examples of the epoxy resin (A-8) represented by the formula (14) include EPPN-501H (trade name, manufactured by Nippon Kayaku Co., Ltd., epoxy equivalent of 162 to 172 g/eq., softening point 51 to 57° C.), EPPN-501HY (trade name, manufactured by Nippon Kayaku Co., Ltd., epoxy equivalent of 163 to 175 g/eq., softening point of 57 to 63° C.), and EPPN-502H (trade name, manufactured by Nippon Kayaku Co., Ltd., epoxy equivalent of 158 to 178 g/eq., softening point of 60 to 72° C.).

In the formula (15), s represents an average value and is a real number in the range of 0.1 to 6.

Specific examples of the epoxy resin (A-9) represented by the formula (15) include XD-1000 (trade name, manufactured by Nippon Kayaku Co., Ltd., epoxy equivalent of 245 to 260 g/eq., softening point of 68 to 78° C.).

The compound (B) having a phenolic hydroxyl group, which is included in the negative photosensitive resin composition of the present invention, contains one or more phenol compounds selected from a group consisting of the compounds (B-1) to (B-6) having a phenolic hydroxyl group represented by the formulas (2) to (7). When the hydroxyl equivalent of component (B) is equal to or higher than a predetermined preferable lower limit, good durability can be imparted to the cured product. On the other hand, when the hydroxyl equivalent of component (B) is equal to or lower than a predetermined preferable upper limit, contribution to improvement of strength of the cured film is maintained. The hydroxyl equivalent of component (B) is preferably 90 to 300, and more preferably 90 to 250. Herein, the hydroxyl equivalent means a value measured by a method according to JIS K-0070. These compounds of component (B) may be used alone or in combination of two or more kinds.

In the formula (2), b is an average value and represents a real number in the range of 1 to 10. R₁s each independently represent a hydrogen atom or an alkyl group having 1 to 4 carbon atoms.

Specific examples of the compound (B-1) having a phenolic hydroxyl group represented by the formula (2) include PN-152 (trade name, manufactured by MEIWA PLASTIC INDUSTRIES. LTD., softening point of 50° C., hydroxyl equivalent of 105 g/eq.), H-1 (trade name, manufactured by MEIWA PLASTIC INDUSTRIES, LTD., softening point of 80° C., hydroxyl equivalent of 103 g/eq.), TD-2131 (trade name, manufactured by DIC CORPORATION, softening point of 80° C., hydroxyl equivalent of 105 g/eq.), KA-1160 (trade name, manufactured by DIC CORPORATION, softening point of 81° C., hydroxyl equivalent of 117 g/eq.), and the like.

In the formula (3), c is an average value and represents a real number in the range of 1 to 10. R₂s each independently represent a hydrogen atom or an alkyl group having 1 to 4 carbon atoms.

Specific examples of the compound (B-2) having a phenolic hydroxyl group represented by the formula (3) include GPH-65 (trade name, manufactured by Nippon Kayaku Co., Ltd., softening point of 65° C., hydroxyl equivalent of 200 g/eq.), MEHC-7800H (trade name, manufactured by MEIWA PLASTIC INDUSTRIES, LTD., softening point of 85° C., hydroxyl equivalent of 179 g/eq.), and the like.

In the formula (4), d is an average value and represents a real number in the range of 1 to 10. R₃s each independently represent a hydrogen atom or an alkyl group having 1 to 4 carbon atoms.

Specific examples of the compound (B-3) having a phenolic hydroxyl group represented by the formula (4) include MEHC-7851H (trade name, manufactured by MEIWA PLASTIC INDUSTRIES, LTD., softening point of 84° C., hydroxyl equivalent of 217 g/eq.), and the like.

In the formula (5), e and f are average values and each represent real numbers in the range of 1 to 10. R₄s each independently represent a hydrogen atom or an alkyl group having 1 to 4 carbon atoms.

Specific examples of the compound (B-4) having a phenolic hydroxyl group represented by the formula (5) include MEHC-7841-4S (trade name, manufactured by MEIWA PLASTIC INDUSTRIES, LTD., softening point of 65° C., hydroxyl equivalent of 166 g/eq.), and the like.

In the formula (6), g is an average value and represents a real number in the range of 1 to 10. R₅s each independently represent a hydrogen atom or an alkyl group having 1 to 4 carbon atoms.

Specific examples of the compound (B-5) having a phenolic hydroxyl group represented by the formula (6) include KTG-105 (trade name, manufactured by Nippon Kayaku Co., Ltd., softening point of 103° C., hydroxyl equivalent of 105 g/eq.), MEH-7500 (trade name, manufactured by MEIWA PLASTIC INDUSTRIES, LTD., softening point of 109° C., hydroxyl equivalent of 98 g/eq.), and the like.

In the formula (7), h is an average value and represents a real number in the range of 1 to 10.

Specific examples of the compound (B-6) having a phenolic hydroxyl group represented by the formula (7) include MEH-7600-4H (trade name, MEIWA PLASTIC INDUSTRIES, LTD., softening point of 154° C., hydroxyl equivalent of 101 g/eq.), and the like.

Component (B) contained in the negative photosensitive resin composition of the present invention may be used in combination with a compound having a phenolic hydroxyl group other than the compounds (B-1) to (B-6) having a phenolic hydroxyl group represented by the formulas (2) to (7), and the compound that can be used in combination is not particularly limited.

Component (B) does not need to be added in a large amount, and the blending ratio of component (B) in the negative photosensitive resin composition of the present invention is preferably 1 to 35% by mass and more preferably 5 to 25% by mass with respect to the total of component (A), (B) and (C).

The cationic photopolymerization initiator (C) included in the negative photosensitive resin composition of the present invention contains a compound represented by the formula (8).

The cationic photopolymerization initiator (C) is a compound that is irradiated with ultraviolet light, far ultraviolet light, an excimer laser such as KrF and ArF, or radiation such as X rays and electron beams to generate a cation, in which the cation can serve as a polymerization initiator. Such a cationic photopolymerization initiator is also usually referred to as an energy beam-sensitive acid generator.

Specific examples of a commercially available compound represented by the formula (8) is Irgacure PAG290 (trade name, manufactured by BASF SE).

Component (C) included in the negative photosensitive resin composition of the present invention may be used in combination with a cationic photopolymerization initiator other than the compound represented by the formula (8), and the cationic photopolymerization initiator that can be used in combination is not particularly limited.

The content of component (C) in the negative photosensitive resin composition of the present invention is usually 0.2 to 5% by mass and preferably 0.5 to 3% by mass with respect to the total mass of components (A) and (B).

In order to improve pattern performance, a miscible reactive epoxy monomer may be added to the negative photosensitive resin composition of the present invention. The reactive epoxy monomer referred to herein means a compound having an epoxy group which is liquid or semi-solid at room temperature, having a weight average molecular weight of about 500 or less, and being excluded from the definition of the epoxy resin (A). As a specific example thereof, a glycidyl ether compound which is liquid at room temperature can be used. Examples of the glycidyl ether compound include diethylene glycol diglycidyl ether, hexanediol diglycidyl ether, dimethylolpropane diglycidyl ether, polypropylene glycol diglycidyl ether (ED506, manufactured by ADEKA CORPORATION), trimethylolpropane triglycidyl ether (ED505, manufactured by ADEKA CORPORATION), trimethylolpropane triglycidyl ether (low chlorine type, EX321L, manufactured by Nagase ChemteX Corporation), pentaerythritol tetraglycidyl ether, dicyclopentadiene dimethanol diglycidyl ether (EP4088L, manufactured by ADEKA CORPORATION), and the like. Further, since these epoxy monomers generally have a high chlorine content, it is preferable to use a low chlorine type that has undergone a low chlorine production method or a purification process. These can be used alone, or in mixtures of two or more kinds.

The reactive epoxy monomer component is used for the purpose of improving reactivity of the resist and physical properties of the cured film. Many of the reactive epoxy monomer components are liquid. The blending ratio of this component is not particularly limited, but when component is liquid, it is desirable to blend the component in an amount of 20% by mass or less with respect to the total amount of the negative photosensitive resin composition to avoid inconvenience such that coating becomes sticky after solvent removal and thus mask sticking is likely to occur. From this viewpoint, when blending the reactive epoxy monomer component into the negative photosensitive resin composition, the blending ratio is preferably 10% by mass or less and particularly suitably 7% by mass or less with respect to the total mass of components (A) and (B).

A solvent may be added to the negative photosensitive resin composition of the present invention, in order to reduce viscosity of the composition and improve coating property. As the solvent, an organic solvent usually used for inks, paints, and the like, which can dissolve each component of the photosensitive resin composition, can be used without particular limitation. Specific examples of the solvent include ketones such as acetone, ethyl methyl ketone, cyclohexanone, and cyclopentanone, aromatic hydrocarbons such as toluene, xylene, and tetramethyl benzene, glycol ethers such as ethylene glycol dimethyl ether, dipropylene glycol dimethyl ether, and dipropylene glycol diethyl ether, esters such as ethyl acetate, butyl acetate, butyl cellosolve acetate, carbitol acetate, propylene glycol monomethyl ether acetate, and γ-butyrolactone, alcohols such as methanol, ethanol, cellosolve, and methyl cellosolve, aliphatic hydrocarbons such as octane and decane, petroleum-based solvents such as petroleum ether, petroleum naphtha, hydrogenated petroleum naphtha, and solvent naphtha, and the like.

These solvents can be used alone or in mixtures of two or more kinds. The solvent component is added for the purpose of controlling the film thickness and coatability when applied to a substrate. For properly maintaining solubility of the major components and volatility of components, the liquid viscosity of the composition, and the like, the amount thereof is preferably 95% by mass or less, and more preferably 10 to 90% by mass, in the negative photosensitive resin composition.

In the negative photosensitive resin composition of the present invention, a miscible adhesion-imparting agent may be used for the purpose of improving adhesion of the composition to a substrate. As the adhesion-imparting agent, a coupling agent such as a silane coupling agent or a titanium coupling agent can be used. Preferably, a silane coupling agent is used.

Examples of the silane coupling agent include 3-chloropropyltrimethoxysilane, vinyltrichlorosilane, vinyltriethoxysilane, vinyltrimethoxysilane, vinyltris(2-methoxyethoxy)silane, 3-methacryloxypropyltrimethoxysilane, 2-(3,4-epoxycyclohexyl)ethyltrimethoxysilane, 3-glycidoxypropyltrimethoxysilane, 3-mercaptopropyltrimethoxysilane, 3-aminopropyltriethoxysilane, N-2-(aminoethyl)-3-aminopropyltrimethoxysilane, 3-ureidopropyltriethoxysilane, and the like. These compounds of the adhesion-imparting agent can be used alone or in combination of two or more kinds.

Since the adhesion-imparting agent is unreactive with the major components of the composition, it remains as a residual component after curing, except for a component acting on the substrate interface. The adhesion-imparting agent exerts an effect even in a small amount depending on the substrate, so that it is appropriate to use it within a range where influence such as deterioration in physical properties is not exerted. The use ratio thereof is preferably 15% by mass or less and more preferably 5% by mass or less in the negative photosensitive resin composition.

In the negative photosensitive resin composition of the present invention, a sensitizer may be further used for absorbing ultraviolet light and supplying the absorbed light energy to the cationic photopolymerization initiator. Preferred sensitizers are, for example, thioxanthones and anthracene compounds having alkoxy groups at the 9- and 10-positions (i.e. 9,10-dialkoxyanthracene derivatives). Examples of the alkoxy group include alkoxy groups having 1 to 4 carbon atoms such as a methoxy group, an ethoxy group, a propoxy group, and a butoxy group. The 9,10-dialkoxyanthracene derivative may further have a substituent. Examples of the substituent include halogen atoms such as a fluorine atom, a chlorine atom, a bromine atom, and an iodine atom, alkyl groups having 1 to 4 carbon atoms such as a methyl group, an ethyl group, and a propyl group, sulfonic acid alkyl ester groups, carboxylic acid alkyl ester groups, and the like. Examples of the alkyl in the sulfonic acid alkyl ester group and the carboxylic acid alkyl ester group include alkyls having 1 to 4 carbon atoms such as methyl, ethyl, and propyl. The substitution position of these substituents is preferably the 2-position.

Specific examples of thioxanthones include 2,4-dimethylthioxanthone, 2,4-diethylthioxanthone, 2-chlorothioxanthone, 2,4-diisopropylthioxanthone, 2-isopropylthioxanthone, and the like, 2,4-Diethylthioxanthone (for example, trade name KAYACURE DETX-S, manufactured by Nippon Kayaku Co., Ltd.) or 2-isopropylthioxanthone is preferable.

Examples of the 9,10-dialkoxyanthracene derivative include 9,10-dimethoxyanthracene, 9,10-diethoxyanthracene, 9,10-dipropoxyanthracene, 9,10-dibutoxyanthracene, 9,10-dimethoxy-2-ethylanthracene, 9,10-diethoxy-2-ethylanthracene, 9,10-dipropoxy-2-ethylanthracene, 9,10-dimethoxy-2-chloroanthracene, 9,10-dimethoxyanthracene-2-sulfonic acid methyl ester, 9,10-diethoxyanthracene-2-sulfonic acid methyl ester, 9,10-dimethoxyanthracene-2-carboxylic acid methyl ester, and the like.

These can be used alone, or in mixtures of two or more kinds. It is most preferable to use 2,4-diethylthioxanthone and 9,10-dimethoxv-2-ethvlanthracene. Since the sensitizer component exerts its effect in a small amount, its blending ratio is preferably 30% by mass or less, and more preferably 20% by mass or less based on the amount of component (C).

In the negative photosensitive resin composition of the present invention, when it is necessary to reduce adverse effects of ions derived from component (C), an ion catcher such as alkoxy aluminums such as tnsmethoxy aluminum, trisethoxy aluminum, trisisopropoxy aluminum, isopropoxydiethoxy aluminum, and trisbutoxy aluminum, phenoxy aluminums such as trisphenoxy aluminum and trisparamethylphenoxy aluminum, and organic aluminum compounds such as trisacetoxy aluminum, trisstearato aluminum, trisbutyrato aluminum, trispropionato aluminum, trisacetylacetonato aluminum, tristrifluoroacetylacenato aluminum, trisethylacetoacetato aluminum, diacetylacetonato dipivaloylmethanato aluminum, and diisopropoxy (ethylacetoacetato) aluminum may be added. These compounds of the ion catcher component can be used alone or in combination of two or more kinds. The blending amount thereof may be 10% by mass or less based on the total solid content (all components except for the solvent) of the negative photosensitive resin composition of the present invention.

To the negative photosensitive resin composition of the present invention, various additives such as a thermoplastic resin, a coloring agent, a thickener, a defoaming agent, and a leveling agent can be further added as necessary. Examples of the thermoplastic resin include polyethersulfone, polystyrene, polycarbonate, and the like. Examples of the coloring agent include phthalocyanine blue, phthalocyanine green, iodine green, crystal violet, titanium oxide, carbon black, naphthalene black, and the like. Examples of the thickener include Orben, Benton, montmorillonite, and the like. Examples of the defoaming agent include silicone-based, fluorine-based, and polymer-based defoaming agents. When these additives and the like are used, the usage amount thereof is, for example, 30% by mass or less, as a tentative guide, in the photosensitive resin composition of the present invention, but can be appropriately increased or decreased depending on the purpose of use.

To the negative photosensitive resin composition of the present invention, for example, an inorganic filler such as barium sulfate, barium titanate, silicon oxide, amorphous silica, talc, clay, magnesium carbonate, calcium carbonate, aluminum oxide, aluminum hydroxide, or mica powder can be added. The amount of the inorganic filler may be 60% by mass or less in the negative photosensitive resin composition of the present invention.

The negative photosensitive resin composition of the present invention can be prepared simply by blending component (A), (B) and (C) as essential components, and the solvent and various additives and the like as necessary, followed by mixing and stirring in a usual manner. As necessary, these components may also be dispersed and mixed using a disperser such as a dissolver, a homogenizer, or a three-roll mill. In addition, after mixing, filtration may be further performed using a mesh, a membrane filter, or the like.

The negative photosensitive resin composition of the present invention is preferably used in the state of a solution to which a solvent has been added. In order to use the negative photosensitive resin composition of the present invention dissolved in a solvent, for example, the negative photosensitive resin composition can be applied at a thickness of 0.1 to 1,000 μm using a spin coater, onto a metal substrate made of silicon, aluminum, copper, gold, platinum, or the like, a ceramic substrate made of lithium tantalate, glass, silicon oxide, silicon nitride, or the like, or a substrate made of polyimide, polyethylene terephthalate, or the like. Subsequently, the solvent can be removed under heating conditions of 60 to 130° C. for about 5 to 60 minutes to form a negative photosensitive resin composition layer, then a mask having a predetermined pattern can be placed thereon, and ultraviolet rays can be applied. Next, heating treatment can be performed under conditions of 50 to 130° C. for about 1 to 50 minutes and then an unexposed portion is developed with a liquid developer under conditions of room temperature (for example, 15° C. or more) to 50° C. for about 1 to 180 minutes, so that a pattern can be formed. Finally, heat treatment is performed under conditions of 130 to 200° C. to obtain a cured product that satisfies various desired properties. As the liquid developer, for example, an organic solvent such as γ-butyrolactone, triethylene glycol dimethyl ether, or propylene glycol monomethyl ether acetate, a mixed solution of the organic solvent and water or the like can be used. For development, a paddle-type, spray-type, or shower-type developing device may be used, and ultrasonic irradiation may be performed as necessary. Incidentally, aluminum is mentioned as a preferred metal substrate in using the negative photosensitive resin composition of the present invention.

The negative photosensitive resin composition of the present invention can be formed into a dry film resist by applying the composition onto a base film using a roll coater, a die coater, a knife coater, a bar coater, a gravure coater, or the like, followed by drying it in a drying oven set at 45 to 100° C. to remove a predetermined amount of the solvent, and as necessary, laminating a cover film or the like. At this time, the thickness of the resist on the base film is controlled to 2 to 100 μm. As the base film and the cover film, for example, a film made of polyester, polypropylene, polyethylene, TAC, polyimide, or the like is used. As such a film, as necessary, a film that has been release-treated with a silicone-based release treatment agent, a non-silicone-based release treatment agent, or the like may be used. In order to use this dry film resist, for example, the cover film may be removed, and the dry film may be then transferred to a substrate using a hand roll, a laminator, or the like at a temperature of 40 to 100° C. under a pressure of 0.05 to 2 MPa, followed by exposure, post-exposure baking, development, and heating treatment in the same manner as in the negative photosensitive resin composition dissolved in a solvent.

When the negative photosensitive resin composition is supplied as a dry film as described above, it is possible to omit the steps of application onto a support and drying. This makes it possible to more easily form a cured product pattern using the negative photosensitive resin composition of the present invention.

When the negative photosensitive resin composition of the present invention is used as a MEMS package or a semiconductor package, it can be used in the form of being covered with the negative photosensitive resin composition or a hollow structure of the negative photosensitive resin composition being fabricated. As a substrate for MEMS and semiconductor packages, a substrate obtained by forming a thin metal film of aluminum, gold, copper, chromium, titanium, or the like on a silicon wafer of any of various shapes by sputtering or vapor deposition to a film thickness of 10 to 5,000 Å, followed by microprocessing of the metal by an etching method or the like, is used. In some cases, as an inorganic protection film, a film of silicon oxide or silicon nitride may be further formed to a film thickness of 10 to 10,000 Å. Then, a MEMS or semiconductor device is fabricated or installed on the substrate, and in order to shield the device from the outside air, it is necessary to fabricate a cover or a hollow structure. In the case of being covered with the negative photosensitive resin composition of the present invention, it can be performed by the above method. In addition, in the case of a hollow structure being fabricated, a partition wall may be formed on the substrate by the above method, then a dry film may be further laminated thereon by the above method, and patterning may be performed so as to form a lid on the partition wall, whereby a hollow package structure can be fabricated. Further, after the fabrication, as necessary, heating treatment may be performed at 130 to 200° C. for 10 to 120 minutes, whereby MEMS package parts and semiconductor package parts satisfying various desired properties can be obtained.

Incidentally, the term “package” refers to a sealing method used for blocking invasion of outside air or liquid in order to maintain stability of substrates, wirings, devices, and the like. The package referred in the present invention represents a package having an actuator such as MEMS, a hollow package for packaging an oscillator such as a SAW device, surface protection for preventing deterioration of a semiconductor substrate, printed wiring board, wiring, or the like, resin sealing, or the like. Further, the term “wafer level package” represents a packaging method in which a protection film, terminals, wiring processing, and packaging are performed in a wafer state, followed by cutting into chips.

The negative photosensitive resin composition of the present invention and a cured product thereof exhibit excellent effects in that they have good image resolution and corrosion resistance under moist and heated conditions, and also have excellent adhesion to various substrates other than silicon wafers. Therefore, the cured product of the photosensitive resin composition is used for, for example, in manufacturing of MEMS (microelectro mechanical system) parts, micromachine parts, microfluid parts, μ-TAS (micro total analysis system) parts, inkjet printer parts, microreactor parts, conductive layers, LIGA parts, molds and stamps for micro injection molding and heat embossing, screens or stencils for fine printing applications, MEMS package parts, semiconductor package parts, BioMEMS and bio-photonic devices, printed wiring boards, and the like. Among them, the cured product of the photosensitive resin composition is particularly useful in MEMS package parts and semiconductor package parts.

### EXAMPLES

Hereinafter, the present invention will be described with reference to examples. These examples are merely illustrative for suitably describing the present invention, and the scope of the present invention is not limited to the following examples.

### Examples 1 to 6 and Comparative Examples 1 to 3 (Preparation of Negative Photosensitive Resin Compositions)

Following the blending amounts (unit: parts by mass) shown in Table 1, (A) an epoxy resin, (B) a compound having a phenolic hydroxyl group, and (C) a cationic photopolymerization initiator and other components were stirred and mixed in a flask equipped with a stirrer at 60° C. for 2 hours to obtain negative photosensitive resin compositions of the present invention and for comparison.

### (Application, Drying, Exposure, and Development of Photosensitive Resin Layer)

Onto each of a silicon (Si) wafer substrate, a substrate obtained by plasma CVD deposition of silicon nitride (SiN) on a silicon wafer to a film thickness of 1,000 Å, and an Al (aluminum) substrate, the negative photosensitive resin compositions of Examples 1 to 6 and Comparative Examples 1 to 3 were each applied using a spin coater to a film thickness (film thickness after drying) of 20 μm. Thereafter, it was dried under conditions of 120° C. for 2 minutes using a hot plate to provide each negative photosensitive resin composition layer. The substrate having provided thereon the negative photosensitive resin composition layer was prebaked under conditions of 65° C. for 5 minutes and then 95° C. for 15 minutes using a hot plate, and further subjected to pattern exposure (soft contact, i-line) using an i-line exposure device (i.e. a mask aligner, manufactured by Ushio Inc.). The exposed substrate was post-exposure baked (PEB) at 95° C. for 6 minutes using a hot plate, and then subjected to a development treatment at 23° C. for 6 minutes by a dipping method using propylene glycol monomethyl ether acetate. Then, it was subjected to a hard baking treatment in an oven at 200° C. (under a nitrogen atmosphere) for 60 minutes to obtain a pattern of the resin of the cured negative photosensitive resin composition on each of the Si wafer substrate and the substrate on which the SiN film is formed and the Al substrate.

### (Sensitivity Evaluation of Negative Photosensitive Resin Composition)

In the pattern exposure, an exposure dose resulting in the best mask transfer accuracy was defined as an optimum exposure dose, and the sensitivity of each negative photosensitive resin composition was evaluated. In the evaluation results, the smaller optimum exposure dose value the composition has, the higher the sensitivity. The evaluation results on the Si wafer substrate are shown in Table 1 below.

### (Resolution Evaluation of Negative Photosensitive Resin Composition)

In the pattern exposure at the optimum exposure dose obtained in the sensitivity evaluation of the negative photosensitive resin composition, among resist patterns resolved without residues at a line and space of 1:1, the width of the narrowest pattern adhering to the substrate was measured to evaluate the resolution of the negative photosensitive resin composition. The evaluation results on the Si wafer substrate are shown in Table 1 below.

Evaluation Criteria

◯ (Good): The width of the narrowest pattern was 10 μm or less.

X (Poor): The width of the narrowest pattern was more than 10 μm.

### (Evaluation of Adhesion Force of Negative Photosensitive Resin Composition to Si and SiN)

The adhesion force referred to herein is a shear strength at the time when the pattern is peeled from the substrate by applying a force from the side surface part of the pattern using a shear tool. The higher the value, the higher the adhesion force between the substrate and the resin composition, which is preferable. Specifically, a block-shaped resist pattern of 100 μm×100 μm (film thickness 20 μm) was formed on the substrate at the optimum exposure dose obtained above, and using a bonding tester (manufactured by Rhesca Co., Ltd.), the breaking load was measured when a load was applied from a lateral direction to a position 3 μm in height from the substrate at a speed of 50 μm/sec using a shear tool of 100 μm. The results are shown in Table 1 below.

Evaluation Criteria

◯ (Good): The shear strength was 30 MPa or more.

X (Poor): The shear strength was less than 30 MPa.

### (Evaluation of Corrosion Resistance of Negative Photosensitive Resin Composition to Al)

The Al substrate with the pattern of the resin of the cured negative photosensitive resin composition was put in a moisture and heat tester under conditions of a relative humidity of 100%, and 120° C. for 24 hours, and then corrosion of Al in the resin portion was evaluated. The results are shown in Table 1 below.

Evaluation Criteria

◯: There was no change in appearance

X: There was a change in appearance

TABLE 1
Evaluated composition and evaluation results

| | | | Example | | | | | Comp. Example | | | |
|---|---|---|---|---|---|---|---|---|---|---|---|
| | | | 1 | 2 | 3 | 4 | 5 | 6 | 1 | 2 | 3 |
| Component (A) | KM-N-LCL | A-1 | 40 | 40 | 40 | 40 | 40 | 40 | 50 | 80 | 40 |
| | NC-3009H | A-2 | 15 | 15 | 15 | 15 | 15 | 15 | 19 | 20 | 15 |
| | NER-7604 | A-3 | 20 | 20 | 20 | 20 | 20 | 20 | 25 | 20 | 20 |
| Component (B) | H-1 | B-1 | 20 | | | | | | | | 20 |
| | MEHC-7800H | B-2 | | 20 | | | | | | | |
| | MEHC-7851H | B-3 | | | 20 | | | | | | |
| | MEHC-7841-4S | B-4 | | | | 20 | | | | | |
| | MEH-7500 | B-5 | | | | | 20 | | | | |
| | MEH-7600-4H | B-6 | | | | | | 20 | | | |
| Component (C) | PAC290 | C-1 | 1 | 1 | 1 | 1 | 1 | 1 | 1 | | |
| | SP-172 | C-2 | | | | | | | | 2 | 2 |
| Reactive epoxy monomer | EX-321L | D | 5 | 5 | 5 | 5 | 5 | 5 | 6 | 5 | 5 |
| Coupling agent | S-510 | E | 5 | 5 | 5 | 5 | 5 | 5 | 5 | 5 | 5 |
| Solvent | MMM | F | 30 | 30 | 30 | 30 | 30 | 30 | 30 | 40 | 30 |
| Optimum exposure dose(Si);mJ | | | 140 | 140 | 160 | 140 | 240 | 190 | 190 | 210 | 210 |
| Resolation(Si) | | | ○ | ○ | ○ | ○ | ○ | ○ | ○ | ○ | ○ |
| Adhesion force(Si) | | | ○ | ○ | ○ | ○ | ○ | ○ | ○ | ○ | ○ |
| Adhesion force(SiN) | | | ○ | ○ | ○ | ○ | ○ | ○ | x | ○ | ○ |
| Corrosion resistance(Al) | | | ○ | ○ | ○ | ○ | ○ | ○ | ○ | x | x |

(A-1) to (F) in Table 1 are as follows.

(A-1): Trade name KM-N-LCL, manufactured by Nippon Kayaku Co., Ltd., epoxy equivalent of 210 g/eq., softening point of 85° C., a compound represented by formula (1) (average repetition number a=4)

(A-2): Trade name NC-3000H, manufactured by Nippon Kayaku Co., Ltd., epoxy equivalent of 285 g/eq., softening point of 65° C., a compound represented by formula (9) (average repetition number i=2)

(A-3): Trade name NER-7604, manufactured by Nippon Kayaku Co., Ltd., epoxy equivalent of 347 g/eq., softening point of 71° C., a compound represented by formula (10) (average repetition number n=2, m=4)

(B-1): A compound represented by formula (2), trade name H-1 manufactured by MEIWA PLASTIC INDUSTRIES, LTD., hydroxyl equivalent of 103 g/eq.

(B-2): A compound represented by formula (3), trade name MEHC-7800H manufactured by MEIWA PLASTIC INDUSTRIES, LTD., hydroxyl equivalent of 179 g/eq.

(B-3): A compound represented by formula (4), trade name MEHC-7851H manufactured by MEIWA PLASTIC INDUSTRIES, LTD., hydroxyl equivalent of 217 g/eq.

(B-4): A compound represented by formula (5), trade name MEHC-7841-4S manufactured by MEIWA PLASTIC INDUSTRIES, LTD., hydroxyl equivalent of 166 g/eq.

(B-5): A compound represented by formula (6), trade name MEH-7500 manufactured by MEIWA PLASTIC INDUSTRIES, LTD., hydroxyl equivalent of 98 g/eq.

(B-6): A compound represented by formula (7), trade name MEH-7600-4H manufactured by MEIWA PLASTIC INDUSTRIES, LTD., hydroxyl equivalent of 101 g/eq.

(C-1): A compound represented by formula (8), trade name PAG-290 manufactured by BASF SE

(C-2): A sulfonate-based cationic photopolymerization initiator, trade name SP-172 manufactured by ADEKA CORPORATION, 50 wt % propylene carbonate solution, provided that the blending amounts shown in the table are solid content values.

(D): Trade name EX-321L, manufactured by Nagase ChemteX Corporation, epoxy equivalent of 140 g/eq.

(E): A silane coupling agent (3-glycidoxypropyltrimethoxysilane, trade name S-510, manufactured by Chisso Corporation)

(F): A solvent (ethylene glycol dimethyl ether, trade name Hisolve MMM, manufactured by TOHO Chemical Industry Co., Ltd.)

From the results in Table 1, it has been revealed that the negative photosensitive resin compositions of the present invention (Examples 1 to 6) had higher adhesion to SiN than the negative photosensitive resin composition of Comparative Example 1, and had higher corrosion resistance to the Al substrate than the negative photosensitive resin compositions of Comparative Examples 2 and 3.

### (Evaluation of Adhesion Force of Negative Photosensitive Resin Composition to Various Materials)

In the same manner as the sensitivity evaluation and the adhesion force evaluation to Si and SiN, the adhesion force of each of the negative photosensitive resin compositions of Example 1 and Comparative Example 1 to each of a Cu (copper) substrate, an LT (lithium tantalate) substrate, an Al (aluminum) substrate, a SiO₂ (silicon dioxide) substrate, an Au (gold) substrate, and a Pt (platinum) substrate was evaluated. The results are shown in Table 2 below.

TABLE 2
Evaluated composition and Evaluation results

| | | | | Comp. |
|---|---|---|---|---|
| | | | Example | Example |
| | | | 1 | 1 |
| Component (A) | KM-N-LCL | A-1 | 40 | 50 |
| | NC-3000H | A-2 | 15 | 19 |
| | NER-7604 | A-3 | 20 | 25 |
| Component (B) | H-1 | B-1 | 20 | |
| | MEHC-7800H | B-2 | | |
| | MEHC-7851H | B-3 | | |
| | MEHC-7841-4S | B-4 | | |
| | MEH-7500 | B-5 | | |
| | MEH-7600-4H | B-6 | | |
| Component (C) | PAG290 | C-1 | 1 | 1 |
| | SP-172 | C-2 | | |
| Reactive epoxy | EX-321L | D | 5 | 6 |
| monomer | | | | |
| Coupling agent | S-510 | E | 5 | 5 |
| Solvent | MMM | F | 30 | 30 |
| Adhesion force | Cu | | ∘ | x |
| | LT | | ∘ | x |
| | Al | | ∘ | x |
| | SiO₂ | | ∘ | ∘ |
| | Au | | ∘ | ∘ |
| | Pt | | ∘ | x |

From the results in Table 2, it has been revealed that the negative photosensitive resin composition of the present invention (Example 1) had higher adhesion to various types of substrates than the negative photosensitive resin composition of Comparative Example 1.

### INDUSTRIAL APPLICABILITY

The negative photosensitive resin composition according to the present invention is capable of forming a pattern with high adhesion to various substrates, and is suitable for fields of MEMS package parts, semiconductor packages, and the like. Particularly in polymer capping of a SAW/BAW filter or the like, the photosensitive resin composition of the present invention has both adhesion to various materials and low corrosiveness, and is therefore advantageous in cavity formation at the time of molding.

Specifically, the cured product of the photosensitive resin composition is particularly suitably used for, for example, in manufacturing of MEMS (microelectro mechanical system) parts, micromachine parts, microfluid parts, μ-TAS (micro total analysis system) parts, inkjet printer parts, microreactor parts, conductive layers. LIGA parts, molds and stamps for micro injection molding and heat embossing, screens or stencils for fine printing applications, MEMS package parts, semiconductor package parts, BioMEMS and bio-photonic devices, printed wiring boards, and the like.

1. A negative photosensitive resin composition comprising (A) an epoxy resin, (B) a compound having a phenolic hydroxyl group, and (C) a cationic photopolymerization initiator, wherein
the epoxy resin (A) is
an epoxy resin (A-1) represented by the following formula (1) 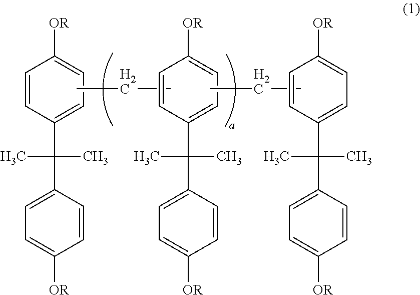
wherein Rs each independently represent a glycidyl group or a hydrogen atom, at least two of a plurality of Rs are glycidyl groups, and a represents an average value of the number of repeating units and is a real number in the range of 0 to 30, and
one or more epoxy resins selected from a group consisting of
an epoxy resin (A-2) represented by the following formula (9) 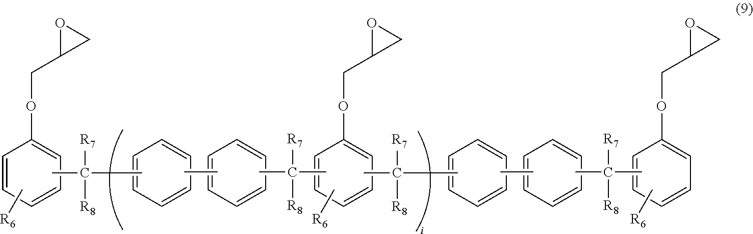
wherein R₆, R₇, and R₈ each independently represent a hydrogen atom or an alkyl group having 1 to 4 carbon atoms, and i represents an average value and is a real number in the range of 1 to 30,
an epoxy resin (A-3) represented by the following formula (10) 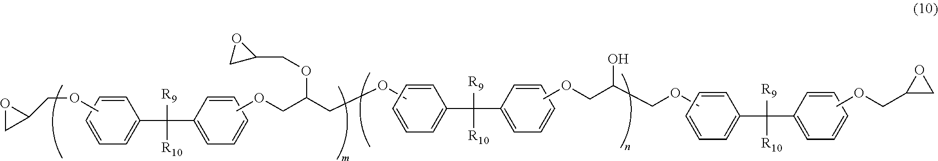
wherein m and n represent average values and are real numbers in the range of 1 to 30, and R₉ and R₁₀ each independently represent a hydrogen atom, an alkyl group having 1 to 4 carbon atoms, or a trifluoromethyl group,
an epoxy resin (A-4) represented by the following formula (11) 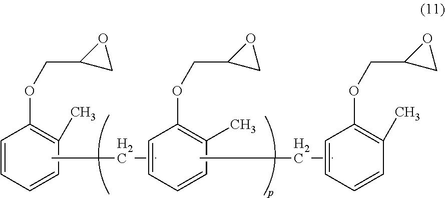
wherein p represents an average value and is a real number in the range of 1 to 30,
an epoxy resin (A-5) which is a reaction product of a phenol derivative represented by the following formula (12) 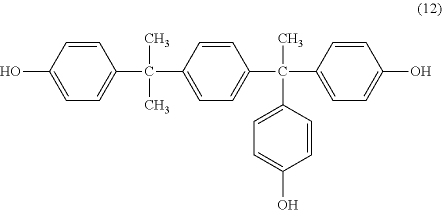 [SMILES: CC(C)(c1ccc(O)cc1)c1ccc(C(C)(c2ccc(O)cc2)c2ccc(O)cc2)cc1]
and an epihalohydrin,
an epoxy resin (A-6) obtained by reacting a polybasic acid anhydride with a reaction product of an epoxy compound having at least two epoxy groups in one molecule and a compound having at least one hydroxyl group and one carboxyl group in one molecule,
an epoxy resin (A-7) represented by the following formula (13) 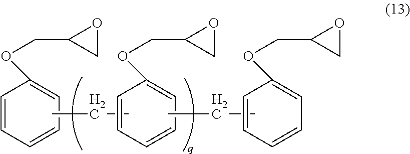
wherein q represents an average value and is a real number in the range of 1 to 10,
an epoxy resin (A-8) represented by the following formula (14) 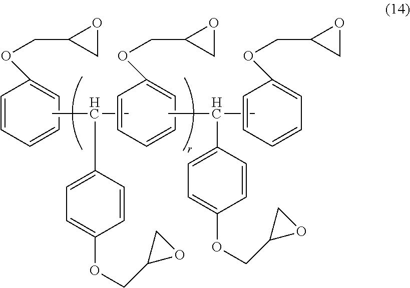
wherein r represents an average value and is a real number in the range of 0.1 to 5, and
an epoxy resin (A-9) represented by the following formula (15) 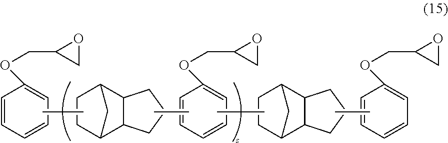
wherein s represents an average value and is a real number in the range of 0.1 to 6,
the only epoxy resin contained in the negative photosensitive resin composition being the epoxy resin (A),
30% by mass or more of the epoxy resin (A) being the epoxy resin (A-1),
and
the compound (B) having a phenolic hydroxyl group contains one or more phenol compounds selected from a group consisting of
a compound (B-1) having a phenolic hydroxyl group represented by the following formula (2) 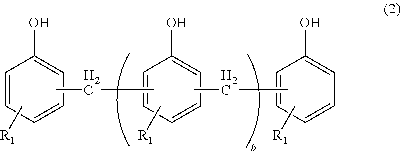
wherein b is an average value and represents a real number in the range of 1 to 10, and R₁s each independently represent a hydrogen atom or an alkyl group having 1 to 4 carbon atoms,
a compound (B-2) having a phenolic hydroxyl group represented by the following formula (3) 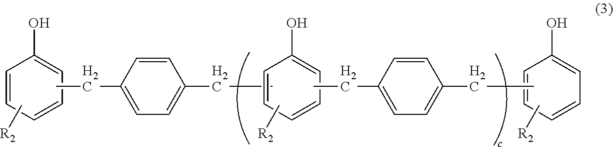
wherein c is an average value and represents a real number in the range of 1 to 10, and R₂s each independently represent a hydrogen atom or an alkyl group having 1 to 4 carbon atoms,
a compound (B-3) having a phenolic hydroxyl group represented by the following formula (4) 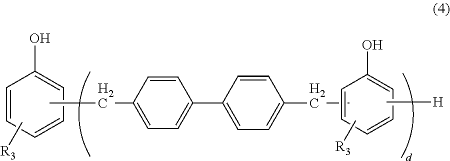
wherein d is an average value and represents a real number in the range of 1 to 10, and R₃s each independently represent a hydrogen atom or an alkyl group having 1 to 4 carbon atoms,
a compound (B-4) having a phenolic hydroxyl group represented by the following formula (5) 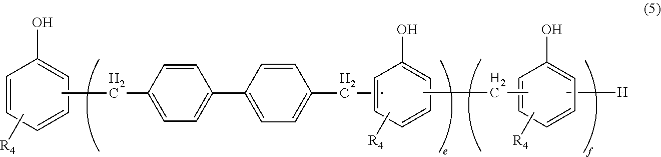
wherein e and f are average values and represent real numbers in the range of 1 to 10, and R₄s each independently represent a hydrogen atom or an alkyl group having 1 to 4 carbon atoms,
a compound (B-5) having a phenolic hydroxyl group represented by the following formula (6) 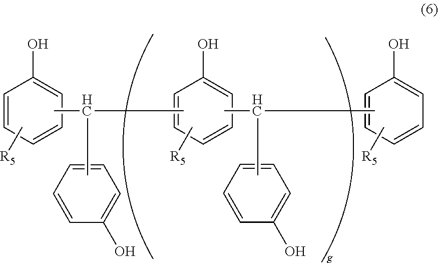
wherein g is an average value and represents a real number in the range of 1 to 10, and R₅s each independently represent a hydrogen atom or an alkyl group having 1 to 4 carbon atoms, and
a compound (B-6) having a phenolic hydroxyl group represented by the following formula (7) 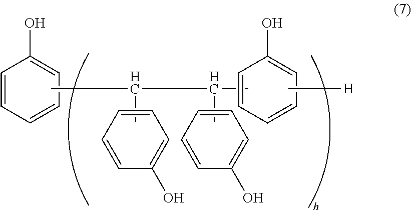
wherein h is an average value and represents a real number in the range of 1 to 10, and
the cationic photopolymerization initiator (C) contains a compound represented b the following formula (8)

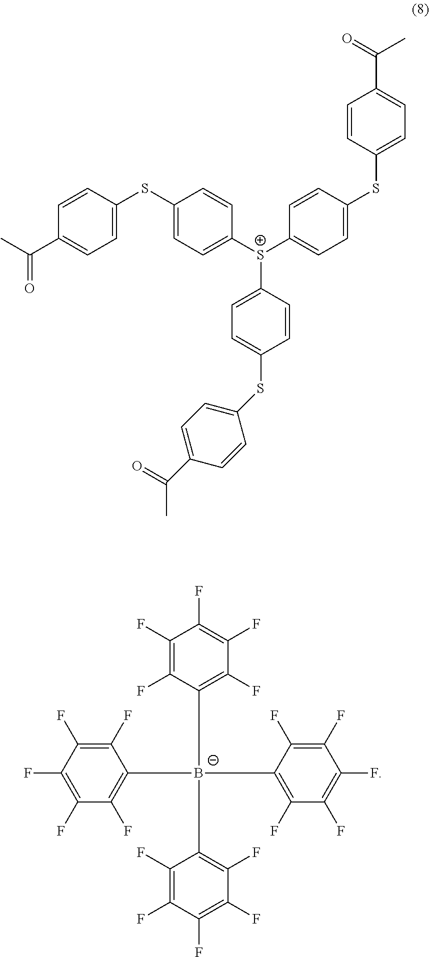 [SMILES: CC(=O)c1ccc(Sc2ccc([S+](c3ccc(Sc4ccc(C(C)=O)cc4)cc3)c3ccc(Sc4ccc(C(C)=O)cc4)cc3)cc2)cc1 ; Fc1c(F)c(F)c([B-](c2c(F)c(F)c(F)c(F)c2F)(c2c(F)c(F)c(F)c(F)c2F)c2c(F)c(F)c(F)c(F)c2F)c(F)c1F]

2. (canceled)

3. A dry film resist comprising the negative photosensitive resin composition according to claim 1.

4. A cured product of the negative photosensitive resin composition according to claim 1.

5. A cured product of the dry film resist according to claim 3.

6. A wafer level package comprising the cured product according to claim 4.

7. An adhesive layer between a substrate and an adherend, wherein the adhesive layer comprises the cured product according to claim 4.

8. A wafer level package comprising the cured product according to claim 5.

9. An adhesive layer between a substrate and an adherend, wherein the adhesive layer comprises the cured product according to claim 5.
